(19) United States
(12) Patent Application Publication
(10) Pub. No.: US 2023/0280978 A1
(43) Pub. Date: Sep. 7, 2023

(54) SPIN ORBIT TORQUE MAGNETIC RANDOM ACCESS MEMORY CELL, SPIN ORBIT TORQUE MAGNETIC RANDOM ACCESS MEMORY ARRAY, AND METHOD FOR CALCULATING HAMMING DISTANCE

(71) Applicant: INSTITUTE OF MICROELECTRONICS, CHINESE ACADEMY OF SCIENCES, Beijing (CN)

(72) Inventors: Guozhong XING, Beijing (CN); Huai LIN, Beijing (CN); Di WANG, Beijing (CN); Long LIU, Beijing (CN); Feng ZHANG, Beijing (CN); Changqing XIE, Beijing (CN); Ling LI, Beijing (CN); Ming LIU, Beijing (CN)

(21) Appl. No.: 18/005,756

(22) PCT Filed: Jan. 21, 2021
(86) PCT No.: PCT/CN2021/073065

§ 371 Date: Jan. 17, 2023

(51) Int. Cl. G06F 7/57; G11C 11/16

(52) U.S. Cl. CPC G06F 7/57; G11C 11/161; G11C 11/1659; G11C 11/1673; G11C 11/1675

(57) ABSTRACT

Provided are a spin orbit torque magnetic random access memory cell, a spin orbit torque magnetic random access memory array and a method for calculating a Hamming distance, wherein the spin orbit torque magnetic random access memory cell includes a magnetic tunnel junction; a first transistor, a drain terminal of the first transistor being connected to a bottom of the magnetic tunnel junction; and a second transistor, a drain terminal of the second transistor being connected to a top of the magnetic tunnel junction.

### CROSS-REFERENCE TO RELATED APPLICATION

This application is a Section 371 National Stage Application of International Application No. PCT/CN2021/073065, filed on Jan. 21, 2021, entitled “SPIN ORBIT TORQUE MAGNETIC RANDOM ACCESS MEMORY CELL, SPIN ORBIT TORQUE MAGNETIC RANDOM ACCESS MEMORY ARRAY, AND METHOD FOR CALCULATING HAMMING DISTANCE”.

### TECHNICAL FIELD

The present disclosure relates to a field of integrated circuit, in particular to a spin orbit torque magnetic random access memory cell, a spin orbit torque magnetic random access memory cell array, and a method for calculating a Hamming distance.

### BACKGROUND

A Hamming weight is defined as the number of non-zero characters in a binary string, and a Hamming distance is defined as the number of different characters at corresponding positions between two equal-length binary strings, which has a wide application in fields of image identification, information coding and information safety.

However, in an information era where a demand for data processing is increasing and a demand for processing speed is increasing, a development of a computing system based on “Von Neumann” architecture is increasingly subject to a problem of “memory wall” caused by a speed difference between a memory and a processor, and a further improvement of a data processing speed and a bandwidth is limited.

Those skilled in the art are eagerly required to develop an in-memory computing architecture based on a non-volatile memory design that is beneficial to breaking through a limitation of memory wall, so as to improve an information processing capability.

### SUMMARY

The present disclosure provides a spin orbit torque magnetic random access memory cell, a spin orbit torque magnetic random access memory cell array, and a method for calculating a Hamming distance, so as to solve the technical problems described above.

According to an aspect of the present disclosure, there is provided a spin orbit torque magnetic random access memory cell, including: a magnetic tunnel junction, a first transistor and a second transistor, wherein a drain terminal of the first transistor is connected with a bottom of the magnetic tunnel junction, and a drain terminal of the second transistor is connected with a top of the magnetic tunnel junction.

In some embodiments of the present disclosure, the magnetic tunnel junction includes a spin orbit coupling layer, a ferromagnetic free layer, a tunneling layer, a ferromagnetic reference layer and a top electrode layer from bottom to top;

the drain terminal of the first transistor is connected with the spin orbit coupling layer, and the drain terminal of the second transistor is connected with the top electrode layer.

In some embodiments of the present disclosure, each of the ferromagnetic free layer and the ferromagnetic reference layer is composed of a material with perpendicular magnetic anisotropy, and the material with perpendicular magnetic anisotropy is any one of CoFeB, Co₂FeAl, Co, CoFe, Fe₃GeTe₂ and Ni₃GeTe₂.

In some embodiments of the present disclosure, an Dzyaloshinskii—Moriya interaction coefficient between the spin orbit coupling layer and the ferromagnetic free layer is 0.1 to 1 mJ/m².

According to an aspect of the present disclosure, there is further provided a spin orbit torque magnetic random access memory array, including: m write word lines, m read word lines, n write bit lines, n read bit lines, n source lines, and m rows and n columns of memory cells, wherein the memory cell is the spin orbit torque magnetic random access memory cell described above, and each of m and n is a positive integer;

each memory cell located in the same column is connected to the same write bit line, each memory cell located in the same column is connected to the same read bit line, and each memory cell located in the same column is connected to the same source line;

each memory cell located in the same row is connected to the same write word line, and each memory cell located in the same row is connected to the same read word line.

According to an aspect of the present disclosure, there is further provided a method for calculating a Hamming distance based on the spin orbit torque magnetic random access memory array described above, including:

turning on the second transistor and injecting an initialization current, so that the magnetic tunnel junction produces a spin transfer torque effect and the magnetic tunnel junction is initialized to a high resistance state;

encoding a first binary string information and a second binary string information in the write bit line and the source line respectively, turning on the first transistor, performing an in-memory XOR operation on the first binary string information and the second binary string information, and storing in-memory XOR operation results in the spin orbit torque magnetic random access memory array; and

turning on the second transistor controlled by the bit read line, reading the in-memory XOR operation results stored in the spin orbit torque magnetic random access memory array according to a voltage difference between the source line and the read bit line, and determining the Hamming distance.

In some embodiments of the present disclosure, the in-memory XOR operation results are stored in the spin orbit torque magnetic random access memory cells located in a diagonal of the spin orbit torque magnetic random access memory array.

In some embodiments of the present disclosure, the first binary string information and the second binary string information include N-bit characters and N is a positive integer.

According to an aspect of the present disclosure, there is further provided a method for calculating a Hamming distance based on the spin orbit torque magnetic random access memory array described above, including:

turning on the second transistor and injecting an initialization current, so that the magnetic tunnel junction produces a spin transfer torque effect and the magnetic tunnel junction is initialized to a high resistance state;

adopting the first binary string information to control N-bit write word lines in one column of the spin orbit torque magnetic random access memory array in parallel, and writing Hamming weights of the first binary string information into the spin orbit torque magnetic random access memory array; adopting a second binary string information to control N-bit write word lines in one column of the spin orbit torque magnetic random access memory array in parallel, writing the first binary string information and the second binary string information in the same mode, so as to perform the in-memory XOR operation of two strings, and storing in-memory XOR operation results in the spin orbit torque magnetic random access memory array, wherein the first binary string information and the second binary string information include N-bit characters, and N is a positive integer; and

turning on the second transistor controlled by the bit read line, reading the in-memory XOR operation results stored in the spin orbit torque magnetic random access memory array according to a voltage difference between the source line and the read bit line, and determining the Hamming distance.

In some embodiments of the present disclosure, the writing Hamming weights of the first binary string information into the spin orbit torque magnetic random access memory array includes:

turning on the first transistor and injecting a writing current into the spin orbit torque magnetic random access memory cell corresponding to a character information, when the character information in the first binary string information is “1”; turning off the first transistor when a character information in the first binary string information is “0”.

### BRIEF DESCRIPTION OF THE DRAWINGS

FIG. 1 shows a schematic structural diagram of a spin orbit torque magnetic random access memory cell according to a first embodiment of the present disclosure.

FIG. 2 shows a schematic diagram of a simulation result of fully electronically controlled magnetization switching implemented by a ferromagnetic free layer in a magnetic tunnel junction.

FIG. 3 shows a schematic diagram of a layout design of a spin orbit torque magnetic random access memory cell according to the first embodiment of the present disclosure.

FIG. 4 shows a schematic diagram of a spin orbit torque magnetic random access memory array according to the first embodiment of the present disclosure.

FIG. 5 shows a block diagram of a method for calculating a Hamming distance calculation according to the first embodiment of the present disclosure.

FIG. 6 shows a schematic diagram of a method for calculating a Hamming distance according to the first embodiment of the present disclosure.

FIG. 7 shows a schematic diagram of reading data from Hamming distance calculation results according to the first embodiment of the present disclosure.

FIG. 8 shows a schematic diagram of a method for calculating a Hamming distance according to a second embodiment of the present disclosure.

FIG. 9 shows a schematic diagram of reading data from Hamming distance calculation results according the second embodiment of the present disclosure.

### DETAILED DESCRIPTION OF EMBODIMENTS

The present disclosure provides a spin orbit torque magnetic random access memory cell, a spin orbit torque magnetic random access memory array and a method for calculating a Hamming distance. The spin orbit torque magnetic random access memory cell includes: a magnetic tunnel junction, a first transistor and a second transistor, wherein a drain terminal of the first transistor is connected with a bottom of the magnetic tunnel junction, and a drain terminal of the second transistor is connected with a top of the magnetic tunnel junction. The present disclosure may implement deterministic magnetization switching without external field under a condition of full electric field, and at the same time have a characteristic of using a non-polar current to switch resistance states.

In order to make the objectives, technical solutions and advantages of the present disclosure more apparent, the present disclosure will be described in further detail below with reference to specific embodiments and accompanying drawings.

Some embodiments of the present disclosure will be described more comprehensively later with reference to the accompanying drawings, and some but not all of the embodiments will be shown. In fact, various embodiments of the present disclosure may be implemented in many different forms and should not be interpreted as being limited to the embodiments set forth herein; in contrast, these embodiments are provided such that the present disclosure meets applicable legal requirements.

In the first exemplary embodiment of the present disclosure, there is provided a spin orbit torque magnetic random access memory cell. FIG. 1 shows a schematic structural diagram of A spin orbit torque magnetic random access memory cell according to the first embodiment of the present disclosure. As shown in FIG. 1, the spin orbit torque magnetic random access memory cell of the present disclosure includes: a magnetic tunnel junction, a first transistor 106 and a second transistor 107, wherein a drain terminal of the first transistor 106 is connected with a bottom of the magnetic tunnel junction, and a drain terminal of the second transistor 107 is connected with a top of the magnetic tunnel junction. The magnetic tunnel junction is a spin orbit torque magnetic tunnel junction (SOT-MTJ).

A structure of the magnetic tunnel junction specifically includes from bottom to top: a spin orbit coupling layer 105, a ferromagnetic free layer 104, a tunneling layer 103, a ferromagnetic reference layer 102, and a top electrode layer 101. The drain terminal of the first transistor 106 is connected with the spin orbit coupling layer 105, and the drain terminal of the second transistor 107 is connected with the top electrode layer 101.

Materials of the ferromagnetic free layer 104 and the ferromagnetic reference layer 102 are selected from any one of CoFeB, Co₂FeAl, CO, or two-dimensional ferromagnetic materials Fe₃GeTe₂ and Ni₃GeTe₂. The Materials have the perpendicular magnetic anisotropy which is conducive to a miniaturization of device size and high speed magnetization switching.

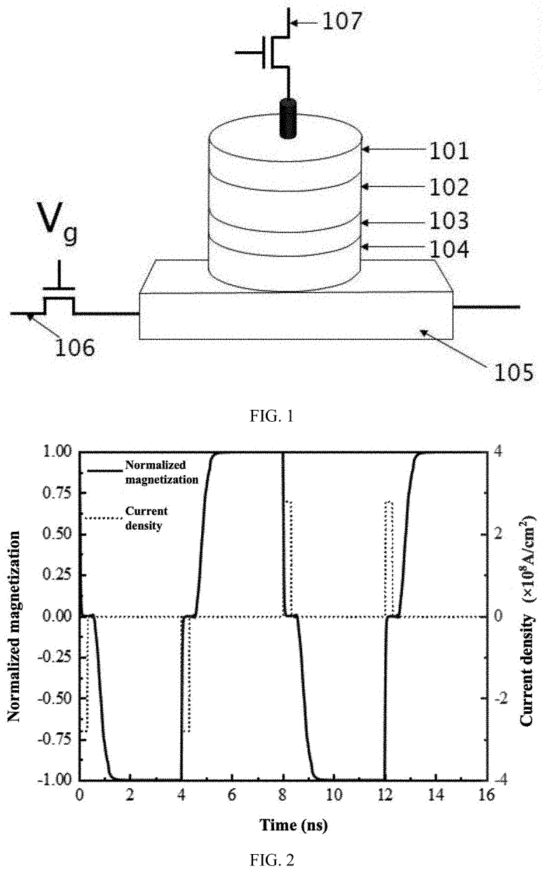

A gate voltage of the first transistor 106 is set to a high level during the writing process. At this point, if there is a voltage drop across the spin orbit torque magnetic random access memory cell, a writing current pulse passes through the spin orbit coupling layer 105. Due to a spin orbit coupling effect of the heavy metal in the spin orbit coupling layer 105, an injected current will produce a spin orbit moment on the ferromagnetic free layer 104, which is usually described by a ratio of a field-like moment and a damping-like moment. Through a DM (Dzyaloshinskii-Moriya) interaction and a ratio λ_{FL}/λ_{DL} of the field-like moment and damping-like moment of the free layer, a combined action of the two effects may achieve the magnetization direction switching without external field assistance in the free layer. A specific operation phenomenon will be described in FIG. 2. When a magnetization direction of the ferromagnetic free layer 104 is the same as that of the ferromagnetic reference layer 102, MRAM presents a low resistance state, which may be represented by binary information “1”; and when the magnetization direction of the ferromagnetic free layer 104 is opposite to that of the ferromagnetic reference layer 102, the MRAM presents a high resistance state, which may be represented by binary information “0”.

A gate voltage of the second transistor 107 is set to a high level during the reading process, and the second transistor 107 is turned on. At this point, a reading voltage difference is generated between the top electrode and the spin orbit coupling layer 105. According to Kirchhoff's law, resistance states stored in the spin orbit torque magnetic random access memory cells are different. Therefore, the high-resistance state and the low-resistance state generate different current values, respectively.

A specific writing process is shown in FIG. 2. A modulation DM interaction coefficient of D=0.3 mJ/m², and λ_{F}/λ_{DL}=0.02 is a requirement of field free switching simulated by MuMax3 software simulation in FIG. 2. In order to describe a switching process, an initial state of the spin orbit torque magnetic random access memory cell is set to a high resistance state with a ratio M_{z}/Mₛ=1. M_{z}/Mₛ is a perpendicular magnetization component to a saturation magnetization component of the ferromagnetic free layer 104. At this point, the first pulse is injected into the ferromagnetic free layer 104, wherein a current density of the first pulse Jc=−2.78×10⁸ A/cm², a current direction of the first pulse is positive from the first transistor 106 to the magnetic tunnel junction (and vice versa), and the pulse width of the first pulse is 0.3 ns. During an application of the first pulse, the magnetization direction of the ferromagnetic free layer 104 changes from spin-up to in-plane, i.e. M_{z}/Mₛ=0, and then relaxes to a position opposite to the initial state after the pulse is applied. Therefore, the magnetization direction is downward, and M_{z}/Mₛ=−1, which implements a change of resistance state of the spin orbit torque magnetic random access memory cell from high resistance to low resistance, and an overall switching time is <2 ns. A second pulse that is exactly the same as the first pulse is applied at 4 ns, and the magnetization direction is switched back to the initial high resistance state, which verifies a resistance state switching of SOT-MRAM without external field assistance under a condition of negative current. A positive third pulse is applied at 8 ns, and a current amplitude and a pulse width of the third pulse are the same as those of the first pulse and the second pulse. At this point, the magnetization change of the spin orbit torque magnetic random access memory cell shows the same result as the first pulse, which is switching the spin orbit torque magnetic random access memory cell from the high resistance state to the low resistance state. Finally, the fourth pulse as the same as the third pulse is applied, which also implements a switching process of the resistance state. The current operation described above further verifies a non-polar writing operation of the spin orbit torque magnetic random access memory cell, the present disclosure makes the switching of the resistance state only depend on a presence or absence of the pulse, not on a amplitude of the current pulse or a current polarity. Compared to amplitude-determined or polarity-determined memristors, the design may be simpler.

It may be understood by those skilled in the art that the parameters described above vary according to material systems and physical dimension and other conditions, which are not specifically limited.

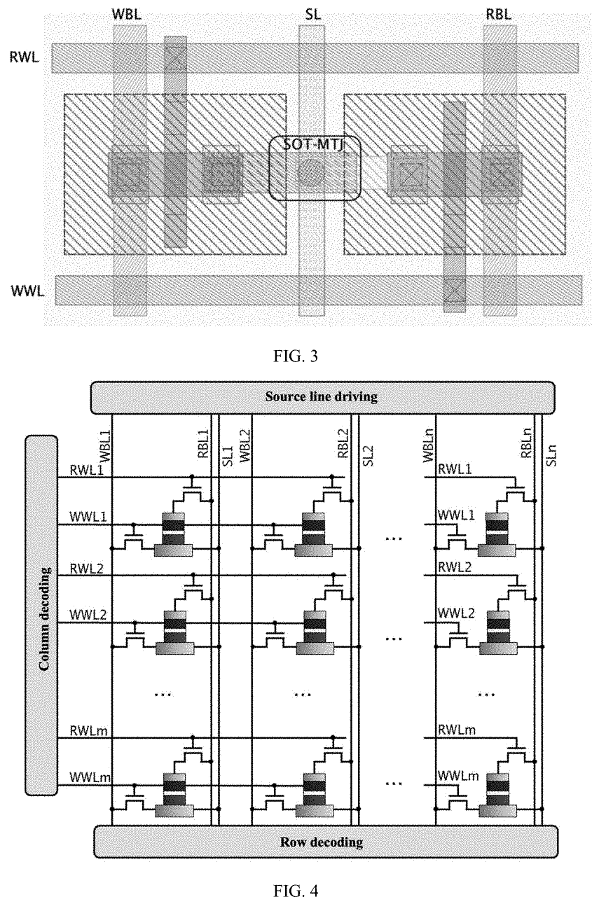

FIG. 3 shows a schematic diagram of a layout design of a spin orbit torque magnetic random access memory cell according to the first embodiment of the present disclosure. As shown in FIG. 3, in the spin orbit torque magnetic random access memory cell provided by the present disclosure, a gate terminal of the first transistor 106 is connected to a write word line (WWL), a gate of the second transistor 107 is connected to a read word line (RWL), and one terminal of the magnetic tunnel junction that is not connected to the first transistor 106 and the second transistor 107 is connected to a source line (SL).

In the first exemplary embodiment of the present disclosure, a spin-orbit moment magnetic random access memory array is also provided. FIG. 4 shows a schematic diagram of a spin orbit torque magnetic random access memory array according to the first embodiment of the present disclosure. As shown in FIG. 4, the spin orbit torque magnetic random access memory array provided by the present disclosure includes: m write word lines, m read word lines, n write bit lines, n read bit lines, n source lines, and m rows and n columns of memory cells, wherein the memory cell is the spin orbit torque magnetic random access memory cell described above, and m and n are positive integers. Each of the memory cells located in the same column is connected to the same write bit line (WBL), each of the memory cells located in the same column is connected to the same read bit line (RBL), and each of the memory cells located in the same column is connected to the same source line (SL). Each of the memory cells located in the same row is connected with the same write word line (WWL), and each of the memory cells located in the same row is connected with the same read word line (RWL).

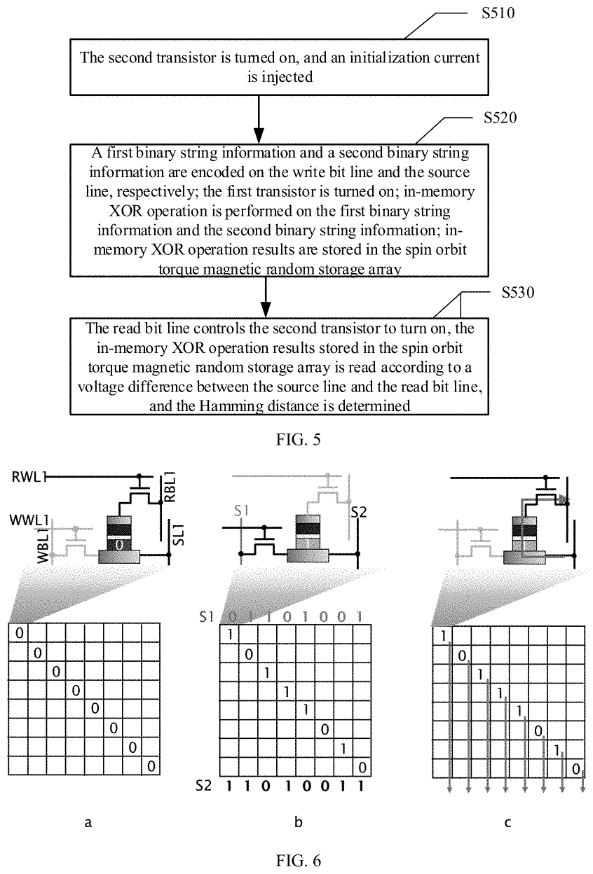

In the first exemplary embodiment of the present disclosure, there is provided a method for calculating the Hamming distance based on the spin orbit torque magnetic random access memory array as described above. FIG. 5 shows a block diagram of a method for calculating the Hamming distance according to the first embodiment of the present disclosure. As shown in FIG. 5, the method for calculating the Hamming distance provided in the first embodiment of the present disclosure includes following operations.

In operation S510, the second transistor is turned on, and an initialization current is injected, so that the magnetic tunnel junction produces a spin transfer torque effect and the magnetic tunnel junction forms a high resistance state. Combined with (a) of FIG. 6, the memory cell needs to be initialized before writing and calculation. At this point, the read word line (RWL) is set to a high level, and a gate voltage is applied to the second transistor to turn on the second transistor. The initialization current at this point passes through the magnetic tunnel junction, and, the magnetization direction of the ferromagnetic free layer 104 is switched to make the magnetization direction of the ferromagnetic free layer 104 opposite to the magnetization direction of the reference layer by the spin transfer torque effect, and “0” is written to the magnetization selected in the spin orbit torque magnetic random access memory array. Therefore, the magnetic tunnel junction at this point is in the high resistance state (HRS).

In operation S520, the first binary string information and the second binary string information are encoded on the write bit line and the source line, respectively; the first transistor is turned on; in-memory XOR operation is performed on the first binary string information and the second binary string information; in-memory XOR operation results are stored in the spin orbit torque magnetic random access memory array. Combined with (b) of FIG. 6, when one character in the first binary string information or the second binary string information is “0”, it represents a low level, and it represents a high level which is “1”. If the first binary string information and the second binary string information have the same character, that is, both are “0” or both are “1”, then there is no potential difference across the spin orbit coupling layer 105 of the spin orbit torque magnetic random access memory cell, and at this point, the data stored in the spin orbit torque magnetic random access memory cell remains initial high resistance state. If the pair of characters of the first binary string information and the second binary string information are different, that is, one character is “0” and the other character is “1”, then a potential difference is generated across the spin orbit coupling layer 105 of the spin orbit torque magnetic random access memory cell. Then, a current flows through the spin orbit coupling layer 105 with a smaller resistance, and a spin current is generated through the spin orbit coupling effect, and a torque effect is generated on the ferromagnetic material of the ferromagnetic free layer 104 of the magnetic tunnel junction. At this point, the data stored in the spin orbit torque magnetic random access memory cell will be switched from the high resistance state to the low resistance state.

Taking an eight-bit string with N=8 as an example, the first binary string information S1=“01101001”, the second binary string information S2=“11010011”, and the operation described above implements XOR logic operation of each character between the first binary string information S1 and the second binary string information S2 with equal length, and stores operation result “10111010” in the diagonal memory cells of MRAM array, wherein the number of operation results “1” is the Hamming distance between the first binary string information S1 and the second binary string information S2.

In operation S530, the read bit line controls the second transistor to turn on, the in-memory XOR operation results stored in the spin orbit torque magnetic random access memory array is read according to a voltage difference between the source line and the read bit line, and the Hamming distance is determined.

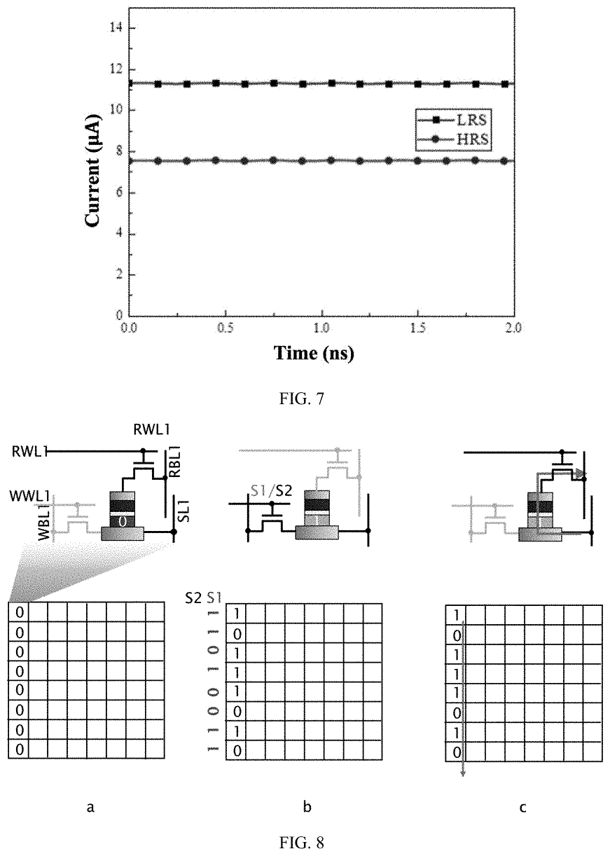

As shown in (c) of FIG. 6, during a read operation, the write word line (WWL) is set to a low level, and the read word line (RWL) is set to a high level, the first transistor is turned off, and the second transistor is turned on. At this point, a reading voltage is applied to the source line (SL), a voltage drop is generated between the read bit line (RBL) and the source line (SL), and a resistance state stored in the magnetic tunnel junction may be read according to a read current flowing through the magnetic tunnel junction. Referred to FIG. 7, the high resistance state (HRS) and the low resistance state (LRS) correspond to read currents of a single spin orbit torque magnetic random access memory cell in the high-resistance state and the low-resistance state, respectively. The two states may be read and distinguished through a peripheral amplification circuit, so as to implement the reading of the Hamming distance operation results stored in the SOT-MRAM. The operations described above may be performed in parallel, and the size of array is not limited to 8×8, which may speed up an efficiency of data processing.

In a second exemplary embodiment of the present disclosure, a method for calculating a Hamming distance based on the spin orbit torque magnetic random access memory array as described above is provided. Compared with the method for calculating a Hamming distance of the first embodiment, the method for calculating a Hamming distance of this embodiment is different in that: a first binary string information and a second binary string information are asynchronously encoded in write word lines. Specifically, in a first cycle, the first binary string information controls m-bit write word lines of a certain column of the spin orbit torque magnetic random access memory array in parallel, and when one character information is “1”, the first transistor is turned on, a writing current is injected into the spin orbit torque magnetic random access memory array; and when one character information is “0”, the first transistor is turned off, no current flows through the MRAM, and its initial information remains unchanged. Thereby, Hamming weights of the first binary string information S1 is written into the MRAM array. In a second cycle, the second binary string information controls write word lines of a certain column of the memory array in parallel, implements the XOR operations of the first binary string information and the second binary string information, and stores the results in the corresponding spin orbit torque magnetic random access memory cells.

As shown in (a) of FIG. 8, the spin orbit torque magnetic random access memory cell needs to be initialized before writing and calculation, and this operation is the same as that in the first embodiment, which will not be repeated here.

A string is used as the signal of write word line (WWL), and performs writing and calculation by controlling the gate voltage of the first transistor, as shown in (b) of FIG. 8).

When a character is “0”, the write word line (WWL) is at a low level, and the first transistor is turned off. When a character is “1”, the write word line (WWL) is at a high level, and the first transistor is turned on. In the first writing cycle, the first binary string information is firstly input into the same column of the spin orbit torque magnetic random access memory array, and each character corresponds to one spin orbit torque magnetic random access memory cell. When the character in the first binary string information is “0”, the first transistor corresponding to the spin orbit torque magnetic random access memory cell is turned off. At this point, the data stored in the spin orbit torque magnetic random access memory array remains initial high resistance state. When the character in the first binary string information is “1”, the first transistor is turned on, a current flows through the spin orbit coupling layer 105, and a spin current is generated through the spin orbit coupling effect, and a torque effect is generated on the ferromagnetic material of the ferromagnetic free layer 104 of the magnetic tunnel junction. At this point, the data stored in the spin orbit torque magnetic random access memory cell is switched from the high resistance state to the low resistance state. The operation stores the information of the Hamming weights (i.e., the number of “1”) in the first binary string information. In a second writing cycle, the second binary string information is used as the gate control voltage to be written into the spin orbit magnetic random access memory array. When the character in the first binary string information is “0”, the first transistor corresponding to the spin orbit magnetic random access memory cell is turned off. At this point, the data stored in the spin orbit magnetic random access memory array remains unchanged, which is same as the stored resistance state after the first writing cycle. When the character in the first binary string information is “1”, the first transistor is turned on. The current flows through the spin orbit coupling layer 105, a spin current is generated through the spin orbit coupling effect, and a torque effect is generated on the ferromagnetic material of the ferromagnetic free layer 104 of the magnetic tunnel junction. At this point, the data stored in the spin orbit torque magnetic random access memory cell is switched, which is different from the result after the first writing cycle, so as to implement XOR operation of the corresponding characters in the first binary string information and the second binary string information.

Similarly, taking an eight-bit string with N=8 as an example, the first binary string information S1=“01101001”, and the second binary string information S2=“11010011”. After the first writing period is finished, the information stored in the spin orbit magnetic random access memory array is “01101001”; after the second writing period is finished, the information stored in the spin orbit magnetic random access memory array is “10111010”. After the second cycle is finished, the number of “1” stored is the Hamming distance of two strings.

The write word lines (WWL) in the column where the calculation is performed are set to a low level during reading, and the read word lines (RWL) are set to a high level. The first transistor is turned off, the second transistor is turned on, and a reading voltage is applied to the source line, so that a voltage drop is generated between the read bit line and the source line, and the number of low resistance states stored in the magnetic tunnel junction may be reflected according to a total current flowing through the magnetic tunnel junction (as shown by an arrow in (c) of FIG. 8), so as to obtain the Hamming distance.

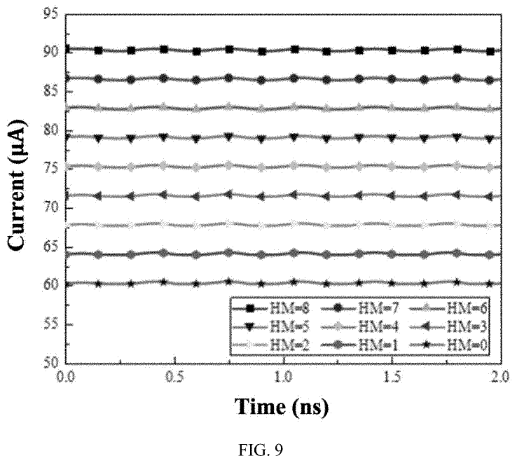

FIG. 9 shows a schematic diagram of reading data from a Hamming distance calculation result according the second embodiment of the present disclosure. As shown in FIG. 9, the first binary string information and the second binary string information are both eight-bit strings with N =8, and when all characters of the eight-bit strings are the same correspondingly, a calculation result of the spin orbit torque magnetic random access memory array is “00000000”, all memory cells are in a high resistance state, and a total current obtained is about 60 μA. At this point, the corresponding Hamming distance is “0”. When all the characters of the first binary string information and the second binary string information are different correspondingly, a calculation result of the spin orbit torque magnetic random access memory array is “1111111”, the spin orbit torque magnetic random access memory cells are all in a low resistance state, a total current obtained is about 90 μA. At this point, the corresponding Hamming distance is “8”. For the remaining intermediate cases, generated currents and Hamming distance calculation results reflected by the currents are shown in FIG. 9. By utilizing a certain column of the spin orbit torque magnetic random access memory array to perform calculation, compared with the method of utilizing operation of the cell located in the diagonal in the first embodiment, an utilization rate of the array is increased while the strings are written in parallel.

For the purpose of brief description, any descriptions of technical features in the first embodiment described above that may be used in the same application are incorporated herein, and the same descriptions will not be repeated.

So far, the embodiments of the present disclosure have been described in detail in combination with the drawings. It should be noted that the implementations not shown or described in the drawings or the text of the description are of forms known to those of ordinary skill in the art and are not described in detail. In addition, the definitions of each element and method described above are not limited to various specific structures, shapes or modes mentioned in the embodiments, and those of ordinary skill in the art may make simple modifications or substitutions, for example:

the shape of the memory cell may be simply replaced by a cuboid, a ring, or the like.

Based on the description described above, those skilled in the art should have a clear understanding of the spin orbit torque magnetic random access memory cell, the spin orbit torque magnetic random access memory array and the method for calculating a Hamming distance of the present disclosure.

It should be seen from the technical solutions described above that the spin orbit torque magnetic random access memory cell, a spin orbit torque magnetic random access memory cell, a spin orbit torque magnetic random access memory cell array, and a method for calculating a Hamming distance provided by the present disclosure have at least one or a part of following beneficial effects.

(1) The spin orbit torque magnetic random access memory cell provided by the present disclosure may implement deterministic magnetization switching without external field under a condition of full electric field, have a nanosecond-level write speed, may be used in the implementation of nanosecond-level high-speed and low write delay in-memory computing array based on a unique circuit design, and have a low power consumption.

(2) The spin orbit torque magnetic random access memory array provided by the present disclosure may utilize voltage control to implement Hamming weight storage and Hamming distance calculation of strings in 2 to 3 operation cycles.

(3) The spin orbit torque magnetic random access memory cell provided by the present disclosure has a simple structure, and material system is compatible with CMOS process, which is favorable for large-scale fabrication and integration.

(4) The spin orbit torque magnetic random access memory cell provided by the present disclosure solves a dependence on an external magnetic field, and a reconfigurable logic operation improve a flexibility of the in-memory computing array of the spin orbit torque magnetic random access memory cell. Compared with the prior art, the present disclosure may implement high-speed Hamming distance calculation and storage of results with a smaller area overhead.

In summary, the present disclosure provides a spin orbit torque magnetic random access memory cell, a spin orbit torque magnetic random access memory array, and a method for calculating a Hamming distance, which may implement high-speed Hamming distance calculation and storage of results with a smaller area overhead, and has important application prospects.

It should also be noted that directional terms mentioned in the embodiments, such as “upper”, “lower”, “front”, “rear”, “left”, “right”, etc., are only directions referring to the drawings, and are not intended to limit the protection scope of the present disclosure. Throughout the drawings, the same elements are represented by the same or similar reference signs. Conventional structures or configurations will be omitted when they may obscure the understanding of the present disclosure.

Moreover, the shape and size of each component in the drawings do not reflect the real size and proportion, but only illustrate the contents of the embodiments of the present disclosure. In addition, in the claims, any reference symbol in parentheses shall not be constructed as a limitation of the claims.

Unless otherwise indicated, the numerical parameters in the description and the attached claims are approximations that may vary depending upon the desired properties obtained through the contents of the present disclosure. Specifically, all numbers expressing quantities of ingredients, reaction conditions, and so forth used in the description and claims should be understood as being modified by the term “about” in all instances. In general, the meaning of the expression is meant to encompass variations of a specified number by ±10% in some embodiments, by ±5% in some embodiments, by ±1% in some embodiments, by ±0.5% in some embodiments.

Furthermore, the word “comprising” does not exclude the presence of elements or steps not listed in the claims. The word “a” or “an” preceding an element does not exclude the presence of a plurality of such elements.

The use of ordinal numbers such as “first”, “second”, “third”, etc. in the description and the claims to modify the corresponding elements, does not mean that the elements have any ordinal numbers, nor does it represent an order between one element and another element, or an order in the manufacturing method. The use of these ordinal numbers is merely used to clearly distinguish an element with a certain name from another element with the same name.

Furthermore, unless the steps are specifically described or must occur sequentially, an order of the steps described above is not limited to that listed above, and may be varied or rearranged according to desired design. Moreover, the embodiments described above may be mixed and matched with each other or with other embodiments based on design and reliability considerations. That is, technical features in different embodiments may be freely combined to form more embodiments.

Similarly, it should be understood that in the foregoing description of exemplary embodiments of the present disclosure, various features of the present disclosure are sometimes grouped together in a single embodiment, figure, or description thereof for the purpose of simplifying the present disclosure and aiding in the understanding of one or more of the various disclosed aspects. However, the disclosed method should not be construed as reflecting the intention that the present disclosure sought to be protected contains more features than the features expressly recited in each claim. More specifically, as reflected in the appended claims, the disclosed aspects contain less than all features of the single embodiment disclosed above. Therefore, the claims following the specific embodiment are hereby expressly incorporated into the specific embodiment, with each claim standing on its own as a separate embodiment of the present disclosure.

The specific embodiments described above further detail the objectives, technical solutions and beneficial effects of the present disclosure. It should be understood that the above are only specific embodiments of the present disclosure, and are not intended to limit the scope of the present disclosure, and any modifications, equivalent substitutions, improvements and the like made within the spirit and principle of the present disclosure should all fall within the protection scope of the present disclosure.

1. A spin orbit torque magnetic random access memory cell, comprising:
a magnetic, tunnel junction;
a first transistor, a drain terminal of the first transistor being connected to a bottom of the magnetic tunnel junction; and
a second transistor, a drain terminal of the second transistor being connected to a top of the magnetic tunnel junction.

2. The spin orbit torque magnetic random access memory cell according to claim 1, wherein the magnetic tunnel junction comprises: a spin orbit coupling layer, a ferromagnetic free layer, a tunneling layer, a ferromagnetic reference layer, a top electrode layer, from bottom to top;
the drain terminal of the first transistor is connected with the spin orbit coupling layer, the drain terminal of the second transistor is connected with the top electrode layer.

3. The spin orbit torque magnetic random access memory cell according to claim 2, wherein each of the ferromagnetic free layer and the ferromagnetic reference layer is composed of a material with perpendicular magnetic anisotropy, and the material with perpendicular magnetic anisotropy is any one of CoFeB, Co₂FeAl, Co, CoFe, Fe₃GeTe₂ and Ni₃GeTe₂.

The spin orbit torque magnetic random access memory cell according to claim 2, wherein, Dzyaloshinskii-Moriya interaction coefficient between the spin orbit coupling layer and the ferromagnetic free layer is 0.1 to 1 mJ/m².

5. A spin orbit torque magnetic random access memory array, comprising: m write word lines, m read word lines, n write bit lines, n read bit lines, n source lines, and m rows and n columns of memory cells, wherein the memory cell is the spin orbit torque magnetic random access memory cell according to claim 1, and each of m and n is a positive integer;
each memory cell located in the same column is connected to the same write bit line, each memory cell located in the same column is connected to the same read bit line, and each memory cell located in the same column is connected to the same source line;
each memory cell located in the same row is connected to the same write word line, and each memory cell located in the same row is connected to the same read word line.

6. A method for calculating a Hamming distance based on the spin orbit torque magnetic random access memory array according to claim 5, comprising:
turning on the second transistor and injecting an initialization current, so that the magnetic tunnel junction produces a spin transfer torque effect and the magnetic tunnel junction is initialized to a high resistance state;
encoding a first binary string information and a second binary string information in the write bit line and the source line, respectively, turning on the first transistor, performing an in-memory XOR operation on the first binary string information and the second binary string information, and storing in-memory XOR operation results in the spin orbit torque magnetic random access memory array; and
turning on the second transistor controlled by the bit read line, reading the in-memory XOR operation results stored in the spin orbit torque magnetic random access memory array according to a voltage difference between the source line and the read bit line, and determining the Hamming distance.

7. The method for calculating a Hamming distance according to claim 6, wherein the in-memory XOR operation results are stored in the spin orbit torque magnetic random access memory cells located in a diagonal of the spin orbit torque magnetic random access memory array.

8. The method for calculating a Hamming distance according to claim 6, wherein the first binary string information and the second binary string information comprise N-bit characters, and N is a positive integer.

9. A method for calculating a Hamming distance based on the spin orbit torque magnetic random access memory array according to claim 5, comprising:
turning on the second transistor and injecting an initialization current, so that the magnetic tunnel junction produces a spin transfer torque effect and the magnetic tunnel junction is initialized to a high resistance state;
adopting a first binary string information to control N-bit write word lines in one column of the spin orbit torque magnetic random access memory array in parallel, and writing Hamming weights of the first binary string information into the spin orbit torque magnetic random access memory array; adopting a second binary string information to control N-bit write word lines in one column of the spin orbit torque magnetic random access memory array in parallel, writing the first binary string information and the second binary string information in the same mode, so as to perform an in-memory XOR operation of two strings, and storing in-memory XOR operation results in the spin orbit torque magnetic random access memory array, wherein the first binary string information and the second binary string information comprise N-bit characters and N is a positive integer; and
turning on the second transistor controlled by the bit read line, reading the in-memory XOR operation results stored in the spin orbit torque magnetic random access memory array according to a voltage difference between the source line and the read bit line, and determining the Hamming distance.

10. The method for calculating a Hamming distance according to claim 9, wherein writing Hamming weights of the first binary string information into the spin orbit torque magnetic random access memory array comprises:
tuning on the first transistor and injecting a writing current into the spin orbit torque magnetic random access memory cell corresponding to a character information, when the character information in the first binary string information is “1”; turning off the first transistor when a character information in the first binary string information is “0”.
